(19) United States
(12) Patent Application Publication
(10) Pub. No.: US 2007/0004121 A1
(43) Pub. Date: Jan. 4, 2007

(54) Electronic assembly and method for producing an electronic assembly

(76) Inventors: Gerald Eckstein, Munchen (DE); Oliver Freudenberg, Munchen (DE); Gunter Muller, Nurnberg (DE); Michael Schier, Miesbach (DE); Stefan Wirth, Erlangen (DE)

Correspondence Address: HARNESS, DICKEY & PIERCE, P.L.C., P.O.BOX 8910, RESTON, VA, 20195, US

(21) Appl. No.: 11/473,227

(22) Filed: Jun. 23, 2006

(30) Foreign Application Priority Data
Jun. 24, 2005 (DE) 10 2005 029 784.6

(51) Int. Cl. H01L 21/8238

(52) U.S. Cl. 438/202

(57) ABSTRACT

A method for producing an electronic assembly and an electronic assembly which has been correspondingly produced are specified. In this case, CMOS structures are formed in a semiconductor substrate to form a circuit and, after the CMOS structures have been formed, at least one electrical conductor is introduced, in a low-temperature process into an opening in the semiconductor substrate in such a manner that the electrical conductor is formed between a first side and a second side, which is opposite the first side, of the semiconductor substrate to connect the circuit. The electronic assembly allows a close arrangement of electronics and detectors and is suitable, for example, for a medical apparatus.

### PRIORITY STATEMENT

The present application hereby claims priority under 35 U.S.C. §119 on German patent application number DE 10 2005 029 784.6 filed Jun. 24, 2005, the entire contents of which is hereby incorporated herein by reference.

### FIELD

The invention generally relates to an electronic assembly, for example for a medical apparatus, and/or to a method for producing an electronic assembly.

### BACKGROUND

WO 2004/012274 A1 discloses a photodetector matrix. Each photodetector is in the form of a photodiode in a substrate, each photodiode being in the form of an active region on a surface of the substrate. A conductive via connection is formed, for each photodiode, from the upper surface to a lower surface of the substrate in order to electrically connect the active region of each photodiode to the lower surface of the substrate. A multiplicity of detectors is arranged such that they adjoin one another in order to form the matrix. An imaging system having a photodetector matrix of this type, having a radiation source which faces the photodetector matrix and having control means for controlling the detectors of the photodetector matrix and of the radiation source is also disclosed.

In WO 2004/012274 A1, a hole having a high length-to-diameter ratio is introduced, by way of plasma etching, into the substrate of a photodiode to be formed. The conductive plated-through hole (also called via) which is then formed in the hole and extends from a first surface of the photodiode substrate to a second surface of the photodiode substrate is insulated from the substrate. In addition, the via contains polysilicon as the conductor, which is epitaxially deposited on the inner walls in a high-temperature process. For the purpose of insulation, the inner walls of the via are oxidized beforehand, in a high-temperature process, to form silicon dioxide.

### SUMMARY

At least one embodiment of the invention includes an object of specifying a method for producing an electronic assembly, which method forms the latter as reliably as possible. At least one embodiment of the invention further includes an object of specifying an electronic assembly which makes it possible, in particular, to closely arrange electronics in detectors.

In process steps of a method of at least one embodiment, CMOS structures (in this case, the abbreviation CMOS stands for Complementary Metal Oxide Semiconductor) are formed in a semiconductor substrate in order to form a circuit. CMOS structures have NMOS field effect transistors (in this case, “IN” stands for Negative Polarity) and PMOS field effect transistors (in this case, “P” stands for Positive Polarity) which are connected to one another within the circuit. In the present case, CMOS structures are also understood here as meaning BiCMOS structures, i.e. a combination of bipolar transistors and field effect transistors, and HV CMOS structures, i.e. high-voltage CMOS structures.

In order to form CMOS structures, a gate oxide is produced and polysilicon, for example, is deposited on the gate oxide in order to form a gate electrode of the field effect transistor. In addition, dopants are implanted in the semiconductor substrate to the side of the gate oxide, the dopants forming drain and source semiconductor regions of the corresponding field effect transistor in subsequent method steps. After the surface of the polysilicon and of the drain and source semiconductor regions has been silicided, a metalization for connecting the gate electrode to the drain and source semiconductor regions is applied in order to form the CMOS structures.

After this formation of the CMOS structures, at least one electrical conductor is introduced, in a low-temperature process, in particular at temperatures of less than 450° C., into an opening in the semiconductor substrate in such a manner that the electrical conductor is formed between a first side and a second side, which is opposite the first side, of the semiconductor substrate. In this case, a low-temperature process is understood as meaning a process which does not impair the quality and method of operation of the CMOS structures which already exist. In contrast, a high-temperature process could impair or even destroy the metalization for connecting the gate electrode and the drain and source semiconductor regions.

This electrical conductor is used to connect the circuit to a further component of the electronics such as circuit parts on another substrate or a connection pin.

In a further process step of the production method of at least one embodiment, detectors are advantageously connected to the CMOS structures by being bonded to one another or being connected to the CMOS structures using metalizations. In this case, the detectors are advantageously arranged in the CMOS structures. The detectors are preferably arranged on and/or next to the CMOS structures, preferably such that they adjoin the latter. Sensors for electromagnetic radiation, in particular for visible light, for UV or X-ray radiation, are generally suitable as detectors.

Also suitable as a detector is a detector design which is connected to the CMOS structures and in which scintillators for converting electromagnetic radiation, in particular X-ray radiation, into radiation at an appropriate wavelength which is suitable for detection by the sensors are connected upstream of the sensors. In this case, the sensors may also be directly embedded into the semiconductor substrate next to the CMOS structures. A design of this type is particularly suitable for use in an X-ray tomograph. Alternatively, a so-called direct converter which directly converts the X-ray radiation into electrical signals is conceivable as a detector which is connected to the CMOS structures.

One advantageous development provides for the CMOS structures to be formed on the first side of the semiconductor substrate, which is also referred to as the front side. In this case, the detectors are preferably arranged on this first side. Main pads which are also called front-end pads are used for contact-connection from this first side. To this end, these main pads are preferably formed on this first side of the semiconductor substrate. At least one secondary pad is formed on the first side of the semiconductor substrate. The secondary pad preferably adjoins the at least one electrical conductor. In this case, a pad is understood as meaning a metalization surface of a metalization, which has an appropriate size for contact-connection to another metal, for example to a bonding wire.

The secondary pad is preferably formed in a metalization plane, in particular in the lowermost metalization plane, of the metalization planes of the circuit. Thus, the secondary pad can advantageously be arranged in the immediate vicinity of the semiconductor substrate or adjoins the semiconductor substrate. However, the secondary pad is preferably insulated from the semiconductor substrate by means of a thin dielectric layer.

According to one advantageous refinement of at least one embodiment, the secondary pad is conductively connected to at least one of the main pads. In this case, a metalization is advantageously provided. Alternatively, the secondary pad may also directly adjoin the main pad.

In one development variant of at least one embodiment, the CMOS structures are covered by a first passivation layer. In a subsequent process step, the first passivation layer is locally removed in order to contact-connect the electrical conductor and the electrical conductor is electrically conductively connected by means of a metalization, in particular.

Although the opening in the semiconductor substrate can also be produced mechanically, the semiconductor substrate is etched, according to one preferred development of at least one embodiment of the invention, after the CMOS structures have been formed, in order to form the opening.

In a first etching variant of at least one embodiment, etching is affected at least partially wet-chemically. Potassium hydroxide (KOH), tetramethylammonium hydroxide (TMAH) or choline may be used, for example, as the etchant. Depending on the semiconductor substrate, which comprises, for example, monocrystalline silicon or a silicon carbide atomic lattice, and on the etchant used, different structures are etched into the semiconductor substrate wet-chemically. If, for example, a semiconductor substrate comprising monocrystalline silicon is etched using potassium hydroxide, pyramidal etching structures are formed.

In a second etching variant of at least one embodiment, etching is affected at least partially as plasma etching. For the purpose of plasma etching, ions of a plasma which has been ignited from a noble gas are accelerated onto the semiconductor substrate. Those locations of the semiconductor substrate which are not intended to be etched are protected by a mask in this case. The angle of the accelerated ions with respect to the surface of the semiconductor substrate is preferably changed during etching so that an opening which is, for example, frustoconical can be etched into the semiconductor substrate on the basis of the angles and the mask. Plasma etching is also referred to as ICP (Inductive Coupled Plasma). The variable etching angle with respect to the semiconductor substrate surface can advantageously be set between 50° and 90°.

Wet-chemical etching and dry etching are particularly preferably combined with one another by first of all pre-etching a structure wet-chemically and deep etching this structure by way of dry etching. Alternatively, dry etching into the depth may also first of all be affected and an etching structure may then be produced in the depth of the semiconductor substrate by means of a wet-chemical etching attack.

In a first configuration variant, etching is affected from the first side of the semiconductor substrate. In this case, the CMOS structures have previously been formed in the first side of the semiconductor substrate. In a second configuration variant, etching is affected from the second side of the semiconductor substrate. A metalization, in particular the secondary pad, preferably forms an etching stop which slows down etching at least to a significant extent or generates a signal which can be evaluated in order to stop etching.

According to one refinement of at least one embodiment, following etching, walls of the opening are covered by a second passivation layer, in particular a nitride or oxide. This passivation layer comprising, for example, SiO₂ or Si₃N₄ is deposited in this case using a low-temperature process. In this case, the passivation layer is used to insulate the metal (which is subsequently applied) of the electrical conductor from the semiconductor substrate in order to prevent so-called crosstalk, for example.

One advantageous development of at least one embodiment provides for the second passivation layer to be at least partially covered by a diffusion barrier layer, in particular including tantalum or a tantalum/nickel alloy. Alternatively, the passivation layer may itself form a diffusion barrier layer by using, for passivation, a material which has a small diffusion constant for the metal used in the electrical conductor for temperatures which occur.

In another development which can also be combined, the second passivation layer and/or the diffusion barrier layer is/are at least partially covered by a layer which has a metal for forming a high conductance.

This metal layer is applied, for example, using metal organic deposition (MOCVD=Metal Organic Chemical Vapor Deposition), vapor deposition or sputtering. This metal may be, in particular, tungsten, aluminum or copper.

This metal layer is preferably thickened, by electroplating or electrolessly, with the metal of this layer, with another metal, for example copper, or with a metal alloy, for example copper/nickel. On account of the different rates of deposition, electroless deposition is advantageous, in particular, for relatively small layer thicknesses, while electrodeposition enables a short process time for relatively large layer thicknesses. The opening is preferably completely closed by thickening the metal layer.

One configuration variant of at least one embodiment provides for a solder to be applied to the second side of the semiconductor substrate and to be conductively connected to the electrical conductor. The solder is preferably applied in the form of a solder ball which is used in so-called flip-chip technology to connect the circuit. In a reflow solder process, the solder ball advantageously establishes an electrical and mechanical connection to another component, in particular to another substrate. If the solder is intended to be arranged at the location of the electrical conductor, the solder may be applied directly or may be applied with the interposition of a barrier layer. If the soldered connection is intended to be arranged at another location on the rear side of the semiconductor substrate, a rewiring by applying a metalization layer is necessary.

Another configuration variant of at least one embodiment provides for a further substrate, in particular a wafer, to be bonded to the second side of the semiconductor substrate. In this case, the further substrate is positioned in such a manner that the electrical conductor is connected to circuit structures of the further substrate.

At least one embodiment of the invention further provides an electronic assembly having a circuit with CMOS structures, the CMOS structures being formed in a semiconductor substrate and an electrical conductor being formed at a distance from the CMOS structures between a first side of the semiconductor substrate and a second side, which is opposite the first side, in order to connect the circuit.

Detectors are preferably connected to the circuit. As mentioned, the detectors may be, in particular, photosensitive sensors for electromagnetic radiation in the visible, ultraviolet or X-ray range. The photosensitive detectors are advantageously semiconductor detectors. The circuit which is connected to the detectors is designed to evaluate signals from the detectors. In this case, evaluation of signals is to be understood as meaning any analog or digital processing of the signals, in particular amplification, equalization, analog or digital filtering (signal processor), analog/digital conversion and/or multiplexing of the signals.

A digital CMOS structure is, for example, an inverter which includes an NMOS field effect transistor and a PMOS field effect transistor. An analog CMOS structure is, for example, a differential amplifier which is constructed using NMOS field effect transistors and PMOS field effect transistors or a current mirror which is constructed from NMOS field effect transistors and/or PMOS field effect transistors.

The CMOS structures of the circuit are formed in a semiconductor substrate. This semiconductor substrate may preferably be anisotropically patterned using etching methods. The semiconductor substrate preferably has monocrystalline silicon, silicon carbide, lithium niobate or lithium tantalate which can be anisotropically patterned using dry etching methods (plasma etching) or chemical etching methods.

An electrical conductor is formed at a distance from the CMOS structures between a first side of the semiconductor substrate and a second side, which is opposite the first side, in order to connect the circuit. An electrical conductor of this type may also be referred to as an electrical via structure. Whereas the CMOS structures are formed in the so-called front-end part of the production process, the electrical conductor is formed in the so-called back-end process. In this case, this electronic assembly is preferably produced in accordance with the method explained above.

In one advantageous refinement of at least one embodiment, a secondary pad which adjoins the electrical conductor is conductively connected to at least one main pad of the CMOS structures. In this case, the secondary pad is used to form the electrical conductor, while the main pad makes it possible for the CMOS structure to be connected and tested from that side of the semiconductor substrate which has the CMOS structure, in particular before the electrical conductor is formed.

According to one preferred development of at least one embodiment, the electrical conductor is separated from the semiconductor substrate by a diffusion barrier layer. This diffusion barrier layer preferably completely prevents metal atoms from diffusing into the semiconductor substrate where, as defects, they could impair the function of the CMOS structures.

The electrical conductor preferably has a plurality of layers comprising different metals or different metal alloys. These metals or metal alloys make it possible for the chemical, thermal and electrical properties to be matched to the respective layer which adjoins a boundary area, in particular to a barrier layer or to a metal layer.

According to one example development, the electrical conductor is in the form of a pyramid, at least in sections, in the direction of the depth of the opening. A pyramidal design may be produced, for example, using a wet-chemical etching process. This makes it possible, in particular, for the walls of the opening (which has been produced) to be covered in an improved manner by further layers, in particular by metal layers, in comparison with purely vertical dry etching processes.

In one advantageous refinement of at least one embodiment, the electrical conductor adjoins a conductive region of a further substrate, in particular a wafer, the further substrate being bonded to the semiconductor substrate. The conductive region is, for example, a highly doped semiconductor region or a silicide region.

According to one example development, a plurality of semiconductor substrates is arranged such that they are adjacent to one another. In this case, each semiconductor substrate has a plurality of electrical conductors which are formed between the first side and the second side. In this case, an adjacent arrangement is understood as meaning that no functional element, in particular no bonding wire, is arranged between the semiconductor substrates.

Another aspect of at least one embodiment of the invention is use of an above-described electronic assembly or an above-described method for forming a medical apparatus, in particular a computer tomograph, a magnetic resonance apparatus, an X-ray diagnosing apparatus, an ultrasonic diagnosing apparatus, a positron emission tomograph or a single photon emission computer tomograph.

### BRIEF DESCRIPTION OF THE DRAWINGS

The invention will be explained in more detail below in example embodiments with reference to drawings, in which:

FIG. 1 shows a diagrammatic sectional illustration of part of an electronic assembly;

FIG. 2 shows a diagrammatic sectional illustration of a partial excerpt of an example embodiment of an electronic assembly;

FIG. 3 shows a diagrammatic sectional view through an etching structure in a semiconductor substrate;

FIG. 4 shows a diagrammatic sectional view through an etching structure, which has been filled with metal, in a semiconductor substrate;

FIG. 5a to FIG. 5c show diagrammatic sectional views between process steps for forming an electrical conductor;

FIG. 6a and FIG. 6b show diagrammatic sectional views between process steps of an exemplary embodiment for electrically connecting two substrates using an electrical conductor;

FIG. 7a and FIG. 7b show diagrammatic sectional views between process steps of another exemplary embodiment for electrically connecting two substrates using an electrical conductor;

FIG. 8 shows a diagrammatic sectional view of an example embodiment through a semiconductor structure having a first pyramidal electrical conductor; and

FIG. 9 shows a diagrammatic sectional view of an example embodiment through a semiconductor structure having a second pyramidal electrical conductor.

### DETAILED DESCRIPTION OF THE EXAMPLE EMBODIMENTS

Photodetectors are used in medical imaging systems, in safety technology and in industrial applications. Computer tomography (CT) systems are one known medical application of a photodetector matrix. In a computer tomography system, an X-ray source for producing an X-ray beam and an associated twodimensional photodetector matrix are arranged in a mechanical structure. During operation, the structure is rotated around the object to be recorded in order to obtain X-ray images for all angles of rotation with respect to the object to be recorded.

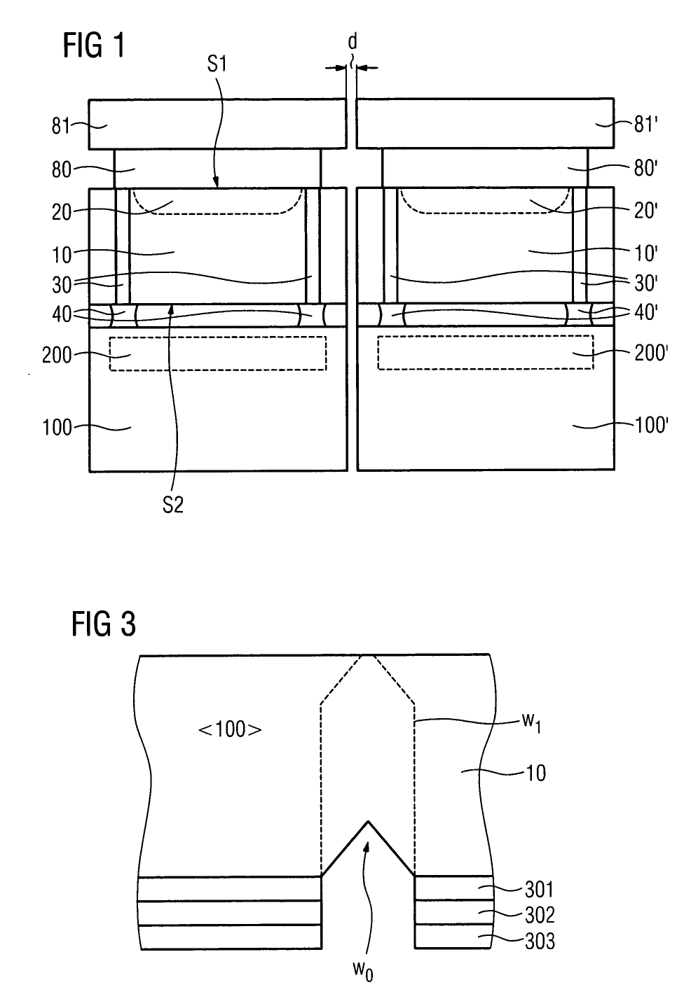

FIG. 1 shows a diagrammatic sectional illustration of part of an electronic assembly which is, for example, a computer tomography (CT) system of this type. The electronic assembly has a photodetector matrix 80, 80′ which is optically coupled to a scintillator 81, 81′. The scintillator 81, 81′ converts X-ray radiation into light which can be detected by the photodetector matrix 80, 80′, for example in the visible or ultraviolet range. The photodetector matrix 80, 80′ is, in turn, arranged on a semiconductor substrate 10, 10′ and is fastened to the latter. The semiconductor substrate 10, 10′ has, for example, a monocrystalline silicon crystal lattice.

CMOS structures 20, 20′ of a circuit are formed in the semiconductor substrate 10, 10′ and make it possible to evaluate signals from the photodetector matrix 80, 80′, for example by way of analog/digital conversion, digital filtering or the like. The CMOS structures 20, 20′ preferably have analog and/or digital circuit components.

A further substrate 100, 100′ having further circuit structures 200, 200′ is arranged below the semiconductor substrate 10, 10′. This substrate is likewise, in particular, a semiconductor substrate having further integrated CMOS structures. Alternatively, this substrate includes ceramic or an epoxy resin board has the further circuit structures 200, 200′.

Electrical conductors 30, 30′ which are formed from a first side S1 of the semiconductor substrate 10, 10′ to a second side S2 of the semiconductor substrate 10, 10′ are formed in the semiconductor substrate 10, 10′. In this case, the electrical conductors 30, 30′ connect the CMOS structures 20, 20′ of the circuit to the further circuit structures 200, 200′ of a further substrate 100, 100′.

The circuit structures 200, 200′ of the further substrate 100, 100′ are electrically and mechanically connected to the electrical conductor 30, 30′ via a soldered connection 40, 40′. It is likewise possible for yet another substrate (which is not illustrated in FIG. 1) to be arranged below the further substrate 100, 100′, the substrate 100, 100′ (which is in the middle in this case) likewise having electrical conductors for connecting the circuit structures 200, 200′.

In order to achieve a detector area which is as large as possible using a plurality of photodetector matrices 80, 80′, at least one first arrangement having a scintillator 81, a photodetector matrix 80 and a semiconductor substrate 10 is arranged such that it is adjacent to a second arrangement having a scintillator 81′, a photodetector matrix 80′ and a semiconductor substrate 10′ without electrical connections in the form of cables or bonding wires being formed between these arrangements. In this case, the distance d is selected to be so minimal that production tolerances or coefficients of thermal expansion are taken into account. The distance d is preferably less than 10 μm, particularly preferably less than 5 μm.

This so-called “stacked” design makes it possible, despite a small lateral extent above one another, to form a high density of circuits 20, 20′, 200, 200′ in the immediate vicinity of the photodetector matrix 80, 80′. This is achieved by way of a multiplicity of electrical conductors 30, 30′ which have been introduced into the semiconductor substrate 10, 10′ following the formation of the CMOS structures 20, 20′.

The following example embodiments of the following figures also show an electrical conductor 30, 30′ which extends through the semiconductor substrate 10, 10′ and states after process steps for forming such an electrical conductor 30, 30′.

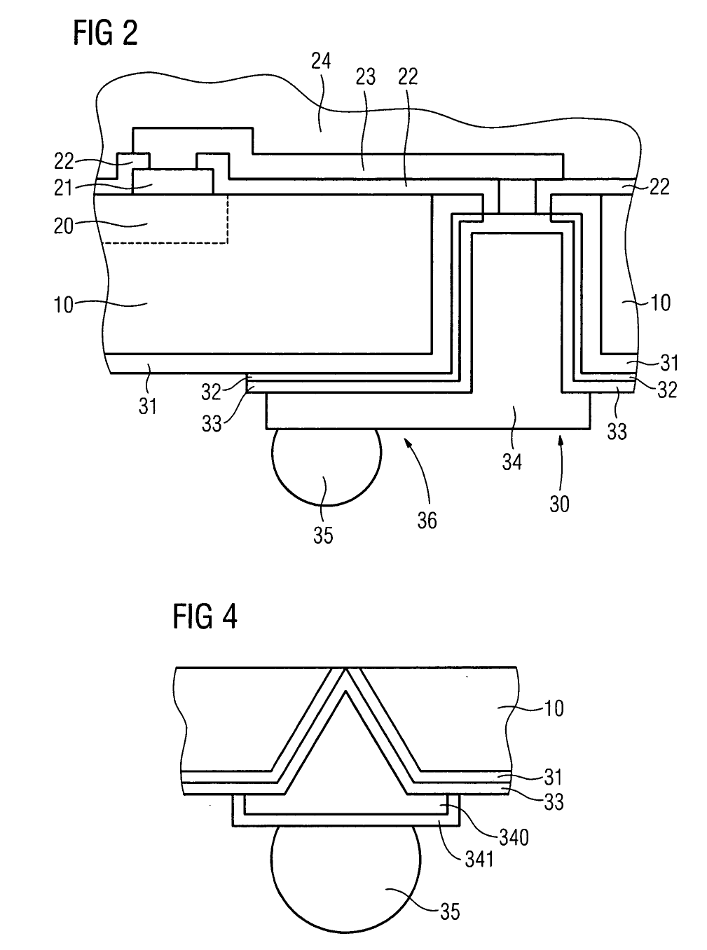

FIG. 2 shows a diagrammatic detail sectional view of the semiconductor substrate 10 having an electrical conductor 30. The CMOS structure 20 which is indicated only diagrammatically has a connection 21 which comprises a metal or a silicide and is conductively connected to a metalization structure 23 having aluminum, for example. Provision is also made of dielectrics 22 and 24 which, as passivation layers, protect the CMOS structures, the semiconductor substrate 10 and the metalization structure 23 from external influences.

An electrical conductor 30 which adjoins the metalization structure 23 and is therefore conductively connected to the latter is introduced into the semiconductor substrate 10. In order to insulate the electrical conductor 30 from the semiconductor substrate 10, the walls of the opening are covered by a dielectric 31 including silicon nitride or silicon dioxide, for example. A diffusion barrier layer 32 comprising TaN, TaSi, TaSiN or TiN, for example, is deposited on the dielectric 31 and prevents metal atoms of the electrical conductor 30 from diffusing into the semiconductor substrate 10.

A thin metal layer 33 having copper, for example, is applied to the diffusion barrier layer 32, the diffusion of copper atoms through the diffusion barrier layer 32 into the semiconductor substrate 10 being prevented. The thin metal layer 33 is applied by virtue of the material being vapordeposited (PVD), sputtered or applied in a low-temperature process using metal organic deposition (MOCVD).

If, instead of copper, use is made of another material which does not significantly diffuse into the semiconductor substrate 10, the diffusion barrier layer 32 may also be omitted and the thin metal layer 33 may be directly applied to the dielectric 31. Layers which advantageously have rhodium, palladium, tungsten, aluminum, titanium and/or copper may be used as the metal layer 33.

In the example embodiment shown in FIG. 2, the opening is filled with a metal 34 by electrodepositing or electrolessly depositing copper or gold, for example, on the thin metal layer 33 in a thickness of 200 μm to 1000 μm. Regions which are not to be coated are covered by a resist or a film during electroplating. A solder ball 35 for flip-chip mounting is also applied to the electrical conductor 30, said solder ball establishing a connection to another conductor on another substrate 100 in a reflow solder process, for example. In the exemplary embodiment illustrated in FIG. 2, the solder ball 35 is arranged at a location other than that of the opening in the semiconductor substrate 10 by means of a rewiring 36 through the metal layers 33, 34, the position of the solder ball 35 being optimized for flip-chip mounting.

FIG. 3 diagrammatically illustrates one preferred example embodiment for forming the opening in the semiconductor substrate 10 having the crystal orientation <100>. A mask having an alternating sequence of a nitride layer and an oxide layer is applied to one side of the semiconductor substrate 10. An Si₃N₄ layer 301, an SiO₂ layer 302 and a further Si₃N₄ layer 303 are illustrated. A structure which forms side walls at an angle of 54.7° is etched wet-chemically into the semiconductor substrate 10 within a window in this mask. Potassium hydroxide, choline or tetramethylammonium hydroxide is used, for example, for the wet-chemical etching.

This structure is etched wet-chemically to the depth w₀. Plasma dry etching (ICP=Inductive Coupled Plasma) is then effected to the depth w₁, the structure of the wet-chemical pre-etching essentially being retained at the depth w₁, as is illustrated using dashed lines in FIG. 3. This makes it possible to cover the walls in the depth of the opening with the diffusion barrier layer 32 or the metal layer 33 in an improved manner. If, as shown in FIG. 1, this structure is etched from the second side S2 which is opposite the first side S1 having the CMOS structures 20, it is not absolutely necessary to further process the first side having the CMOS structures 20.

FIG. 4 shows another example embodiment, the opening being etched into the semiconductor substrate in the form of a pure pyramid. This is advantageous in the case of a thin semiconductor substrate 10, in particular, since the width of the opening depends on the thickness of the semiconductor substrate 10. A filling 340 of gold is electrodeposited on the metal layer 33. The gold deposition is covered by a conductive barrier 341 comprising TiCu in order to prevent the gold from chemically reacting with the materials of the solder ball 35.

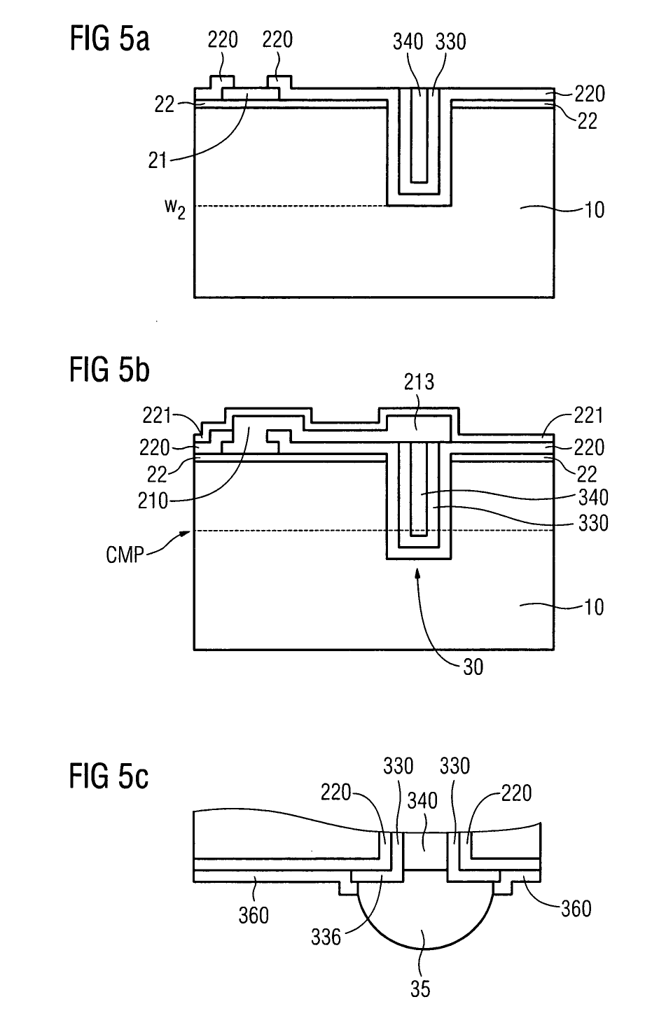

FIGS. 5a to 5c show a plurality of process steps for forming the electrical conductor 30. In this example embodiment, the opening is etched from the first side S1 of the semiconductor substrate 10, in which the CMOS structures are formed. An opening is first of all etched into the front-end passivation 22 on the side S1 having the CMOS structures 20 in order to then protect the front-end pad 21 (main pad) and the CMOS structures 20 following the application of an etching mask comprising a solder resist, a dry resist or a low-temperature silicon nitride or silicon dioxide mask. A via structure is then patterned to a defined depth using a plasma dry etching process (ICP). As shown in FIG. 5a, etching into the semiconductor substrate 10 is affected to a depth w₂ of at least 250 μm, preferably 300 μm.

After the opening has been etched, a passivation layer 220 which may also have a diffusion barrier, if required, is applied to the walls of the opening within the opening. To this end, the passivation layer 220 has, for example, a PECVD nitride layer, a PECVD oxide layer or other dielectrics or parylenes. If metals such as copper or gold are used for the seed layer 330, a diffusion barrier layer (not illustrated in FIGS. 5a to 5c), for example including TiN or TaN, must additionally be deposited in order to prevent copper or gold from diffusing into the silicon of the semiconductor substrate 10. In this case, the diffusion barrier advantageously has a layer thickness of between 10 and 100 nm.

A metal layer 330 which has, for example, aluminum, gold, copper or tungsten and is also referred to as a metallic seed layer is then deposited within the opening. In this case, deposition may be effected using physical or chemical deposition methods. This thin metal layer is then thickened by electrodepositing (Cu, Ni, Au) or electrolessly depositing (Ni, Cu) metals 340; in this case, the opening is advantageously at least partially, preferably completely, filled with metal 340. If the openings for the vias are intended to be only partially filled, the metals 330, 340 will first of all be passivated again using a PECVD nitride layer, a PECVD oxide layer or other dielectrics or parylenes. If, in contrast, the opening for the vias is completely filled, this step may be dispensed with.

The passivation 220 for the front-end pad (main pad) 21 is then chemically or physically opened using etching processes, and further deposition of a metal layer 210 of a metalization plane including aluminum, gold, copper or tungsten, for example, is effected. This metal layer 210 is used to electrically contact-connect the front-end pad 21 to the metal layers 330, 340 of the electrical conductor 30.

A back-end metal pad 213 including aluminum, copper, tungsten or gold, for example, is formed above the metal layers 330, 340, it also being possible to refer to the back-end metal pad 213 as a secondary pad. The back-end metal pad 213 and the metal layer 210 are then covered by a back-end passivation layer 221 including, for example, a dielectric such as PECVD oxide or silicon nitride or polyimide or polybenzoxazole.

The wafer containing the semiconductor substrate 10 is then thinned, by way of chemical mechanical polishing (CMP), to a thickness of 250 μm +/−30 μm to the line CMP depicted using dashed lines in FIG. 5b, so that the electrical conductor 30 forms a via from the first side S1 of the semiconductor substrate 10 having the CMOS structures to the second, opposite side S2 of the semiconductor substrate 10. As a result of the grinding-back process, the metals 330, 340 of the electrical conductor 30 are accessible for contact-connection.

Rear-side processing of the second side S2 of the semiconductor substrate 10 is affected by first of all passivating the second side S2 of the semiconductor substrate using a dielectric, for example, and opening said side in the region of the electrical conductor 30 by way of a photolithographically masked etching process. A thin metal layer 336 for a rear-side rewiring and the application of solder is applied to this opposite second side S2 of the semiconductor substrate 10 using thin-film metalization, said metal layer having, for example, copper, nickel and/or gold. In this case, a passivation layer 360 is again applied to the conductor tracks 336 for the rewiring, the passivation layer 360 being removed again in the region of the pads for the application of solder 35.

If a rewiring on the rear side is intended to be dispensed with, the second side S2 of the semiconductor substrate 10 may be metalized locally in the region of the electrical conductor 30 and the solder 35 may also be applied in the same region.

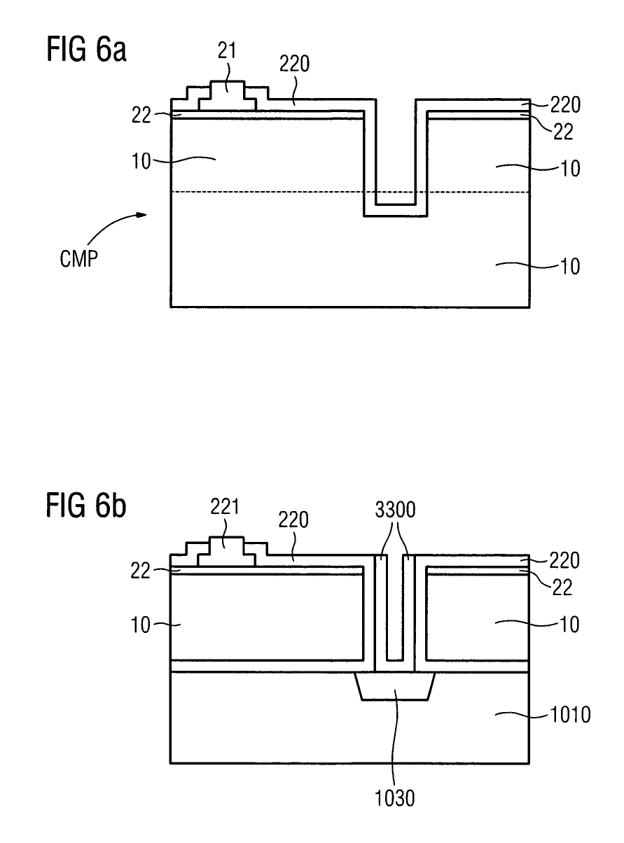

FIGS. 6a and 6b show another example embodiment of the invention in which a wafer is bonded to the semiconductor substrate 10, a first silicon substrate 10 in the example embodiment shown in FIGS. 6a and 6b. In FIG. 6a, after a passivation layer 220 has been applied to walls of the opening, the semiconductor substrate 10 is subjected to chemical mechanical polishing to a thickness (CMP) which is depicted using dashed lines. The wafer which has, in particular, a second monocrystalline silicon substrate 1010 is then bonded to the polished side (S2) of the semiconductor substrate 10. A region 1030 containing dopants having a high dopant concentration is formed in the second monocrystalline silicon substrate 1010 at the location of a contact to a metal layer 3300 within the opening in order to enable a low-impedance connection to the second silicon substrate 1010.

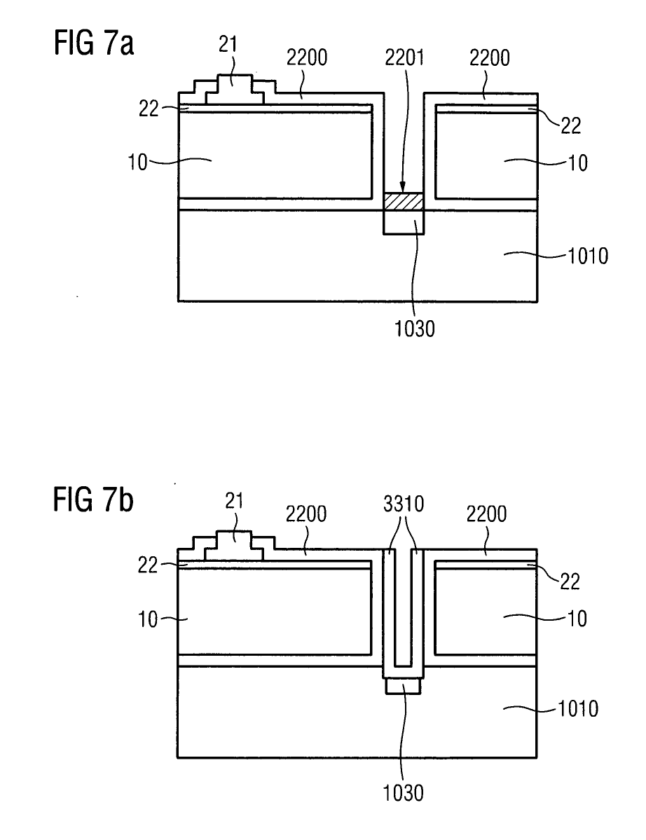

FIGS. 7a and 7b diagrammatically illustrate, in process states, another exemplary embodiment in which a passivation layer 2200 is applied to the walls of the opening only after the wafer has been bonded to the second silicon substrate 1010. The bottom 2201 of the opening is then uncovered from the passivation layer using an etching step and a thin metal layer 3310 which adjoins the highly doped connection semiconductor region of the second silicon substrate 1010 for the purpose of low-impedance contact-connection is introduced into the opening. As an alternative to the highly doped semiconductor region 1030, a metal track may also be provided on the wafer for the purpose of contact-connection.

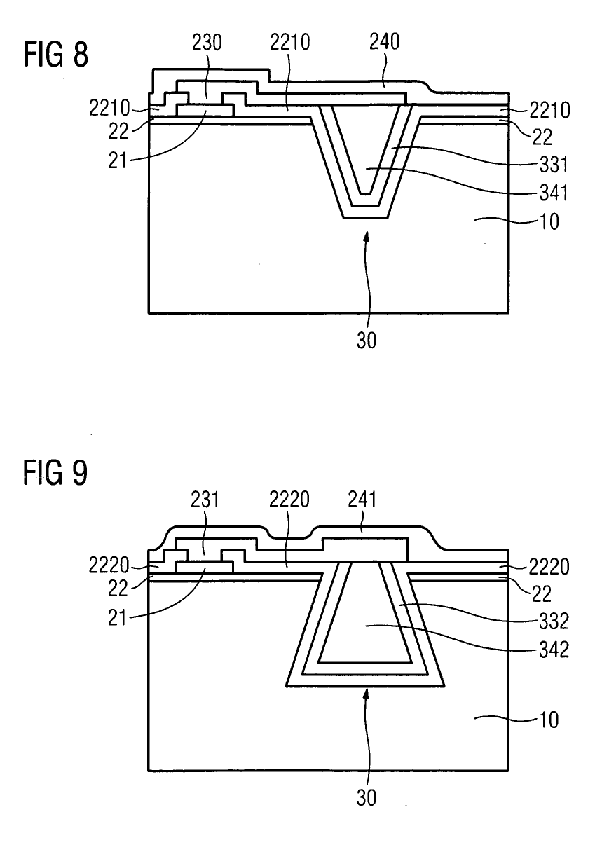

FIG. 8 illustrates an opening which has been filled with metals 331, 341 before a process step of chemical mechanical polishing. FIG. 9 likewise illustrates an opening which has been filled with metals 332, 342 before a process step of chemical mechanical polishing. The metals 331, 341 and 332, 342 are insulated from the semiconductor substrate 10 by means of a passivation layer 2210 and 2220, respectively. The metals 331, 341 and 332, 342 form the electrical conductor 30 in the two example embodiments shown in FIGS. 8 and 9. The pyramidal or conical structure of the opening is affected by way of plasma dry etching with a change in the etching angle of between 60° and 90°. In this case, FIG. 9 shows a structure of the electrical conductor 30 for the case of an undercut caused by the etching angle.

These example embodiments enable improved metalization of the opening with the metals 331, 341 and 332, 342. In the case of direct contact-connection of a pad on the rear side which faces away from the CMOS structures, dry etching for opening a pad metalization for the design variant with an undercut can be configured with greater process reliability.

The example embodiments shown in FIGS. 8 and 9 can advantageously also be changed in such a manner that the semiconductor substrate 10 is etched from both sides in order to form the opening.

What is claimed is:

1. A method for producing an electronic assembly, comprising:
forming CMOS structures in a semiconductor substrate in order to form a circuit;
introducing, after the CMOS structures have been formed, at least one electrical conductor, in a low-temperature process, into an opening in the semiconductor substrate in such a manner that the electrical conductor is formed between a first side and a second side, opposite the first side, of the semiconductor substrate to connect the circuit.

2. The method as claimed in claim 1, wherein detectors are connected to the CMOS structures.

3. The method as claimed in claim 1, wherein
the CMOS structures are formed on the first side of the semiconductor substrate,
main pads for contact-connecting from the first side are formed on this side of the semiconductor substrate, and
a secondary pad is formed on the first side of the semiconductor substrate such that it adjoins the at least one electrical conductor.

4. The method as claimed in claim 3, wherein the secondary pad is formed in one metalization plane of the metalization planes of the circuit.

5. The method as claimed in claim 3, wherein the secondary pad is conductively connected to at least one of the main pads.

6. The method as claimed in claim 1, wherein the CMOS structures are covered by a first passivation layer, and wherein the first passivation layer is locally removed in order to contact-connect the electrical conductor.

7. The method as claimed in claim 1, wherein the semiconductor substrate is etched, after the CMOS structures have been formed, to form the opening.

8. The method as claimed in claim 7, wherein etching is affected at least partially wet-chemically.

9. The method as claimed in claim 7, wherein etching is at least partially effected as plasma etching, in particular in combination with wet-chemical pre-etching.

10. The method as claimed in claim 7, wherein etching is effected from the first side of the semiconductor substrate.

11. The method as claimed in claim 7, wherein etching is effected from the second side of the semiconductor substrate.

12. The method as claimed in claim 7, wherein, following etching, the walls of the openings are covered by a second passivation layer.

13. The method as claimed in claim 12, wherein the second passivation layer is at least partially covered by a diffusion barrier layer.

14. The method as claimed in claim 12, wherein at least one of the second passivation layer and the diffusion barrier layer is at least partially covered by a layer containing a metal.

15. The method as claimed in claim 14, wherein the layer containing metal is thickened, by electroplating or electrolessly, with the metal of this layer, with another metal, or with a metal alloy.

16. The method as claimed in claim 1, wherein a solder is applied to the second side of the semiconductor substrate and is conductively connected to the electrical conductor.

17. The method as claimed in claim 1, wherein a further substrate is bonded to the second side of the semiconductor substrate.

18. An electronic assembly, comprising:
a circuit with CMOS structures, the CMOS structures of the circuit being formed in a semiconductor substrate, and
an electrical conductor, formed at a distance from the CMOS structures between a first side of the semiconductor substrate and a second side, opposite the first side, to connect the circuit.

19. The electronic assembly as claimed in claim 18, wherein the circuit is connected to detectors and is designed to evaluate signals from the detectors.

20. The electronic assembly as claimed in claim 18, wherein a secondary pad adjoins the electrical conductor and is conductively connected to at least one main pad of the CMOS structures.

21. The electronic assembly as claimed in claim 18, wherein the electrical conductor is separated from the semiconductor substrate by a diffusion barrier layer.

22. The electronic assembly as claimed in claim 18, wherein the electrical conductor has a plurality of layers comprising different metals or different metal alloys.

23. The electronic assembly as claimed in claim 18, wherein the electrical conductor is in the form of a pyramid, at least in sections.

24. The electronic assembly as claimed in claim 18, wherein the electrical conductor is bonded to a conductive region of a further substrate, the further substrate being bonded to the semiconductor substrate.

25. The electronic assembly as claimed in claim 18, wherein a plurality of semiconductor substrates having a plurality of electrical conductors, formed between the first side and the second side, are arranged such that they are adjacent to one another.

26. A method, comprising:
using of an electronic assembly as claimed in claim 18 for forming a medical apparatus.

27. The method of claim 26, wherein the medical apparatus is at least one of a computer tomograph, a magnetic resonance apparatus, an X-ray diagnosing apparatus, an ultrasonic diagnosing apparatus, a positron emission tomograph and a single photon emission computer tomograph.

28. A medical apparatus, comprising:
the electronic assembly as claimed in claim 18.

29. The medical apparatus of claim 28, wherein the medical apparatus is at least one of a computer tomograph, a magnetic resonance apparatus, an X-ray diagnosing apparatus, an ultrasonic diagnosing apparatus, a positron emission tomograph and a single photon emission computer tomograph.

30. The method of claim 1, wherein the low-temperature process includes a temperature of less than 450° C.
